(19) United States
(12) Patent Application Publication
(10) Pub. No.: US 2016/0370433 A1
(43) Pub. Date: Dec. 22, 2016

(54) METHOD OF ESTIMATING THE RESIDUAL CAPACITIES OF A PLURALITY OF BATTERIES

(71) Applicant: RENAULT S.A.S., Boulogne-Billancourt (FR)

(72) Inventors: Yann CHAZAL, Paris (FR); Cedric CHANTREL, Charenton Le Pont (FR); Do-Hieu TRINH, Fontenay La Fleury (FR); Philippe TOUSSAINT, Versailies (FR); Mathieu UMLAWSKI, Versailles (FR)

(73) Assignee: RENAULT s.a.s, Boulogne-Billancourt (FR)

(21) Appl. No.: 15/102,462

(22) PCT Filed: Dec. 9, 2014
(86) PCT No.: PCT/FR14/53230

§ 371 Date: Sep. 13, 2016

(30) Foreign Application Priority Data
Dec. 13, 2013 (FR) 1362590

(51) Int. Cl. G01R 31/36

(52) U.S. Cl. CPC G01R 31/3648; G01R 31/3679; G01R 31/3658

(57) ABSTRACT

A method for estimating residual capacities of a plurality of batteries connected to an electrical power distribution network includes storing in the batteries energy coming from the network, releasing to return the energy to the network, gathering information relating to physical quantities to determine a state of ageing of each battery, during the storing, charging a selected battery until a predefined maximum charge level is reached, during the releasing, discharging the selected battery, if the selected battery has reached the maximum charge level during the storing, until a predefined minimum charge level is reached, or making the selected battery inactive if the selected battery has not yet reached the predefined maximum charge level, then measuring a level of energy yielded by the selected battery, and calculating a residual capacity of the selected battery based on the measurement of the level of energy yielded by the battery.

### FIELD OF THE INVENTION

The invention relates to a method for estimating residual capacities of a plurality of connected batteries.

This invention can be applied regardless of battery type.

### PRIOR ART

Connecting a plurality of batteries to supply a power distribution network is known. In particular, electric vehicle batteries can be recycled in order to be used in a stationary environment. Since these batteries do not have enough energy for onboard use such as in electric vehicles, they can on the other hand be used in a stationary environment since they are capable of storing energy and returning it at other times depending on need.

In the field, there is already known from US20120249048 a battery charge/discharge determining device for managing a natural electrical power production plant (e.g. wind power or photovoltaic power), the device comprising an energy storage phase to store energy during periods of production of natural electrical energy and an energy release phase to return this energy outside the production periods. US20120249048 describes the control of the battery contribution, using battery state information which varies with time, notably the state of charge of the battery, the state of ageing of the battery, and voltage or current measurements at the terminals of the battery when it is being charged or discharged.

It has been observed that this type of device exhibits the drawback of not being very accurate and does not take into account all the elements necessary to estimate the actually usable energy of the battery. Furthermore, it involves periodic check interventions by an operator in order to take measurements for estimating various characteristics of the battery, such as its state of ageing. The result of this is an increase in costs of operation of the batteries connected to supply a power distribution network (e.g. staff and maintenance equipment), and periods of unavailability of the batteries during the checking operations.

### Object of the Invention

In this context, an aim of the invention is to overcome at least some of the abovementioned drawbacks, notably to optimize operating costs. Another aim is to ensure a minimum energy level to supply a power distribution network, to improve the precision of checking the residual capacity of each battery in order to estimate the energy actually usable by the battery and to take into account the degradation of components due to their ageing. Another aim is to reduce the equipment needed to manage the residual capacities of this plurality of batteries. Another aim is to reduce costs related to possible breaches in adhering to instructions to keep the plurality of batteries in a state of operation, and the consideration of the state of degradation of the batteries; in other words, reliability and safety of operation of the method over time are objectives. Lastly, the invention aims to automate the method and avoid heavy manual interventions requiring the battery to be isolated from its environment.

The proposed solution is that the method includes the following steps:
gathering information relating to physical quantities in order to determine the state of ageing of each of the batteries from said plurality of batteries,
selecting a battery from said plurality of batteries based on information gathered and/or information relating to a planning of the use of the batteries and/or a user instruction,
during the energy storage phase, charging as a priority said selected battery until a predefined maximum charge level, dependent on the state of ageing, is reached,
during the energy release phase, discharging as a priority said selected battery, if it has reached the maximum charge level during the storage phase, until a predefined minimum charge level, dependent on the state of ageing, is reached, or making said selected battery inactive if it has not yet reached the predefined maximum charge level, then measuring a level of energy yielded by said selected battery,
calculating a residual capacity of said selected battery based on the measurement of the level of energy yielded by said battery.

This solution provides for overcoming the abovementioned problems.

The steps for measuring the yielded energy level and the residual capacity calculation following from this means that the costs of operation of the energy storage system can be optimized, notably as regards equipment and maintenance costs. These steps provide for taking into account the state of ageing of the batteries, the planning of the use of the batteries (and/or a user instruction) to regularly check the operational state of this plurality of batteries connected to one another. Furthermore, these steps provide for tracking the operational degradation of the system and for trying to compensate for it as far as possible. These steps therefore provide for improving the robustness of a system implementing said estimating method.

In one embodiment, the method includes, during the phase for measuring the yielded energy level, making said battery inactive if it still exhibits a state of charge greater than said predefined minimum charge level, while the system is passed back into a storage phase.

In one embodiment, the method includes fixing a predetermined discharge power value in order to discharge, during the release phase, the selected battery, said selected battery discharging only at this predetermined discharge power value, the selected battery ceasing to discharge if the network requires a supply power value less than said discharge power value.

In one embodiment, the method includes:
also processing the gathered information relating to physical quantities in order to detect the presence of an anomaly of the physical quantities in the battery,
selecting as a priority, in order to be charged, the battery exhibiting an anomaly of the physical quantities, the information relating to the planning of the use of the batteries and/or the user instruction then taking lower priority.

In one embodiment, the steps are triggered regularly, preferably periodically.

In one embodiment, the method is implemented by a stationary storage system.

In one embodiment, the method includes comparing said yielded energy level with a guaranteed minimum energy level of the selected battery:
if the yielded energy level is greater than or equal to the guaranteed minimum energy level, then an insufficient capacity check counter is reset,
if the yielded energy level is less than the guaranteed minimum energy level:
   then the counter is incremented by one unit,
   if the counter exceeds a predetermined threshold value, then information to replace this battery is sent, or, an end-of-charge voltage of the battery is incremented.

According to a second object, another aim is a system is for estimating residual capacities of a plurality of batteries comprising means for implementing the method according to any one of the preceding embodiments.

According to a third object, there is also proposed a building comprising an abovementioned system.

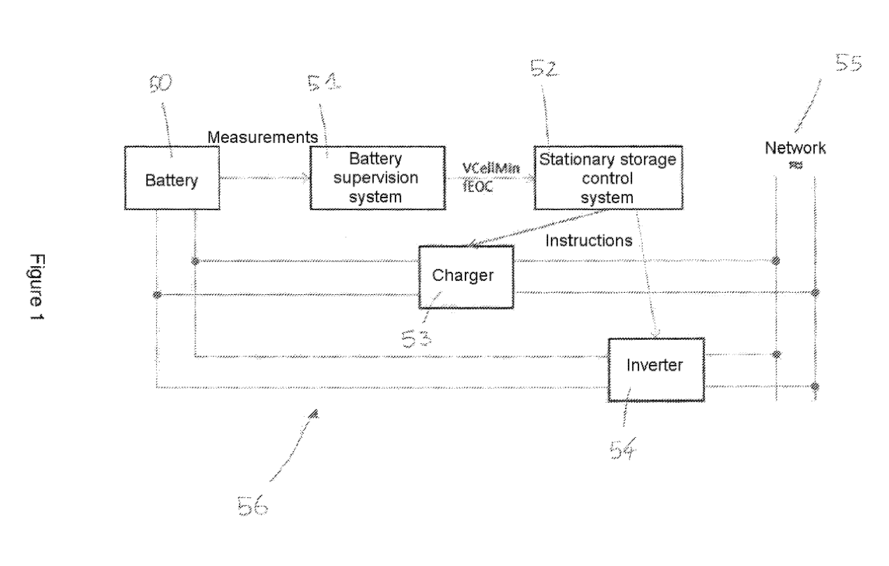

### BRIEF DESCRIPTION OF FIG. 1

FIG. 1 shows an example architecture of the stationary storage system.

### DESCRIPTION OF EXAMPLE EMBODIMENTS OF THE INVENTION

According to the invention, the method comprises a first phase of energy storage to store in a plurality of batteries 50 energy coming from a power distribution network 55 and a second phase of energy release for returning the energy to the power distribution network 55. The method includes the following steps:
gathering information relating to physical quantities in order to determine the state of ageing of each of the batteries 50 from said plurality of batteries 50,
selecting a battery 50 from said plurality of batteries 50 based on information gathered and/or information relating to a planning of the use of the batteries and/or a user instruction,
during said first phase of energy storage, charging as a priority said selected battery (50) until a predefined maximum charge level, dependent on the state of ageing, is reached,
during said second phase of energy release, discharging as a priority said selected battery, until a predefined minimum charge level is reached, or making said selected battery inactive if it has not yet reached the predefined maximum charge level, dependent on the state of ageing, then measuring a level of energy yielded E_{resChk} by said selected battery (50). The method can additionally comprise a step in which it is necessary to make said battery inactive if it still exhibits a state of charge greater than said predefined minimum charge level, while the system is passed back into a storage phase.
calculating a residual capacity of the selected battery 50 based on the measurement of the level of energy yielded E_{resChk} by said battery 50.

Preferably, the set of steps described above are implemented by a stationary storage system 56.

Depending on its ageing, the performance levels of the battery 50 can vary markedly during its use. The stationary storage system 56 checks this information.

The main function of the stationary storage system 56 is to implement the management of information about the state of each battery 50 forming the plurality of batteries 50 in order to enable the plurality of batteries 50 to be used at the maximum of their energy capacities.

The stationary storage system is capable of gathering information relating to physical quantities in order to determine the state of ageing of a battery. This information can be the following (non-exhaustive list):
the temperature at various points of the battery,
the total voltage and current of the battery,
the voltage of each cell of the battery,
the state of charge of the battery,
the remaining available energy in discharge mode, the available power in discharge mode.

Any battery 50 degrades over time, i.e. its total capacity reduces steadily over time, mainly for two reasons:
calendar degradation related to battery usage time at the various states of charge of the battery (between 0% and 100%) and at the temperatures to which it has been subjected,
degradation related to the cycling of the battery 50, related to the energy already discharged by the battery 50.

As FIG. 1 shows, the stationary storage system 56 for residual capacities of a plurality of batteries 50 comprises the following elements:
a battery 50,
a battery supervision system 51,
a stationary storage control system 52,
a charger 53,
an inverter 54.

These elements form the stationary storage system 56. This stationary storage system 56 is connected to the alternating current network 55.

The supervision system 51 for the battery 50 performs the acquisition of physical quantities of the battery (measurements of temperatures, voltages of each of the cells, current, etc). The purpose of these physical quantities is notably to determine the state of ageing of the battery 50. The supervision system 51 for the battery 50 performs calculations based on these measurements in order to, for example, determine:
a minimum voltage of the cells V_{cellMin};
first binary value indicating whether the charging as terminated f_{EOC}=1 or f_{EOC}=0;
a charge power P_{CHG,HVB}, or discharge power P_{DCHG,HVB} which the battery 50 can support without being damaged;
a voltage V_{HVB} and a current measured at the terminals of the battery 50;
a quantity of energy available from the battery 50.

The supervision system 51 for the battery 50 communicates the physical quantities for determining the state of ageing of the battery 50 to the stationary storage control system 52.

The charger 53 and the inverter 54 communicate the achievable power, P_{BCB} and P_{INV} respectively, to the stationary storage control system 52.

In one embodiment, the information gathered relating to physical quantities in order to determine the state of ageing of the battery is also processed to detect the presence of an anomaly of the physical quantities in the battery. Then, the battery 50 exhibiting an anomaly in the physical quantities is selected as a priority in order to be charged, the information relating to the planning of the use of the batteries and/or the user instruction taking lower priority. Preferably, it is the stationary storage control system 56 which processes this gathered information.

This stationary storage control system 52 is subjected to certain energy constraints. For example, the stationary storage control system 52 can request to charge the battery 50 during off-peak periods and to discharge it during high-load periods.

As FIG. 1 shows, the stationary storage control system 52 establishes charging or discharging instructions depending on the information that it receives and on its energy constraints. The instructions are sent to the charger 53 or the inverter 54 to be fulfilled: the battery 50 is charged or discharged.

In the context of a service provision, the minimum energy level guaranteed to the client is E_{2nd,MIN}. The objective of the procedure is to check whether the residual capacity, E_{ResChk}, is sufficient with respect to the guaranteed, minimum energy level E_{2nd,MIN}. If this is not the case, it is necessary to consider either modifying the behavior of the stationary storage control system 52 in order to guarantee the guaranteed minimum energy level E_{2nd,MIN}, for example by further charging the battery 50, or changing the battery 50 connected to the plurality of other batteries 50 to another battery 50 having a higher residual capacity.

The stationary storage control system 52 performs most of the calculations of interest here as part of the present invention.

Thus, the first binary value indicating whether the charging terminated for the battery 50 is equal to f_{EOC2nd}=1 if the minimum voltage of the cells V_{CellMin} is greater than or equal to the end-of-charge voltage V_{cellEOC}. The end-of-charge voltage V_{cellEOC} corresponds to the desired voltage value at the end of charging: the voltage V_{cellEOC} can be adjusted according to the result of the residual capacity check procedure. Its initial value is determined according to the state of ageing of the battery 50 in order that the charged battery 50 (fEOC_{2nd}=1) has a quantity of energy greater than or equal to E_{2nd,MIN}.

A second binary value f_{EODC2nd} indicates that the discharging is terminated for the battery 50; if the discharge power P_{DCHG} is less than or equal to a threshold power, then f_{EODC2nd}=1.

The stationary storage control system 52 can restrict its operation. More specifically, it can prohibit the discharging of the plurality of batteries 50, with only charging then being possible. It can also prohibit the charging of the plurality of batteries, with only discharging then being possible. Of course, the stationary storage control system 52 can be configured so that charging and discharging are possible. These choices are made according to the state of the power distribution network. By way of example, there can be periods when a building requires a contribution of additional electrical energy (the method then being in its second phase of release). In this context, the contribution of the present invention enables this contribution of additional electrical energy. If the power distribution network supplies the building in excess, then the plurality of connected batteries 50 will be in its first phase of energy storage. In this context, it is useful to prohibit the charging or discharging of the plurality of batteries 50.

The residual capacity check procedure for each battery is notably made up of four steps:
triggering the procedure,
charging the battery until the first binary value is obtained (f_{EOC}=1 or f_{EOC2nd}=2),
discharging the battery until the second binary value f_{EODC2nd}=1 is obtained. During discharging, the quantity of energy discharged E_{resChk} (in kWh) is measured,
adjusting the behavior of the stationary storage control system 52 with respect to the result of the discharge; for example, if the energy level E_{resChk} is less than the guaranteed minimum energy level E_{2nd,MIN} of the battery 50, it may for example be decided to discard this battery 50.

Several mechanisms have been put in place to trigger the residual capacity check procedure:
the steps for gathering information relating to physical quantities in order to determine the state of ageing of each of the batteries 50 from said plurality of batteries 50, for selecting a battery 50 from said plurality of batteries 50 based on information gathered and/or information relating to a planning of the use of the batteries and/or a user instruction, for charging as a priority said selected battery 50 during the first phase of storage, for discharging as a priority said selected battery during the second phase of supply, for measuring the level of energy yielded E_{resChk} by said selected battery 50 and for calculating the residual capacity of the selected battery 50 based on the measurement of the level of energy yielded E_{resChk} by said battery, are triggered regularly, preferably periodically, at a determined frequency;
the steps for gathering information relating to physical quantities in order to determine the state of ageing of each of the batteries 50 from said plurality of batteries 50, for selecting a battery 50 from said plurality of batteries 50 based on information gathered and/or information relating to a planning of the use of the batteries and/or a user instruction, for charging as a priority said selected battery 50 during the first phase of storage, for discharging as a priority said selected battery during the second phase of supply, for measuring the level of energy yielded E_{resChk} by said selected battery 50 and for calculating the residual capacity of the selected battery 50 based on the measurement of the level of energy yielded E_{resChk} by said battery, are triggered by an instruction given by a user and communicated to said stationary storage system 56 (preferably to the stationary storage control system 52); a human operator can then give an order to trigger the procedure, either immediately or at a determined time.

The selection of the battery 50 from said plurality of batteries 50 is performed on the basis of the information gathered and/or information relating to a planning of the use of the batteries to which the abovementioned user instruction can be added. “Information relating to a planning of the use of the batteries” is understood here to mean information relating to an order that is predetermined and arbitrary or according to criteria such as the type of battery or the nominal capacity of the battery, independently of information relating to their state of ageing.

When the stationary storage system 56 is made up of several batteries, care will be taken to start the method on one battery 50 at a time. The idea is to preserve to the maximum extent the availability of the system 56 for the user, by requesting the other batteries 50 of the system 56 to take charge of the work that the battery 50 being checked cannot take on temporarily, for example during the second phase of energy supply.

To complete the charging of the battery 50 to be checked, the stationary storage control system 52 exploits periods when the need of the building is that of storing energy. Under these conditions, during the first phase of storage, the battery 50 subjected to the capacity check will take priority (over the other batteries of the complete system) and will exploit the sequence to increase its charge level (with the stationary storage control system 52 driving the charger of the battery).

Conversely, the battery 50, being charged and which has not yet exceeded the predefined maximum charge level will be held inactive in the second phase of energy supply, where the need of the user is that of supplying energy; the other batteries 50 of the system will then be made to contribute. That is a key element of the present invention. This is why the stationary storage control system 52 then prohibits the discharging of the battery, the charge level of which is less than the predefined maximum charge level and establishes that:
the discharge power P_{DCHG} is zero,
P_{CHG,MIN}−min(P_{CHG,LIM}, P_{CHG,HVB}, P_{BCB}) where P_{CHG,MIN} is the maximum achievable power for the charging depending on the precision of the measurement instruments of the storage system; P_{CHG,HVB} is the charge power that the battery can support without being damaged; P_{BCB} is the achievable power of the charger 53;
P_{CHG,MAX}=min(P_{CHG,HVB}, P_{BCB}) where P_{CHG,MAX} is the maximum achievable power for the charging;
E_{CHG}=E_{2nd,MIN}−E_{2nd} where E_{CHG} is the available energy for the charging; E_{2nd} is the available energy of the battery; E_{2nd,MIN} is the guaranteed minimum energy level of the battery;
the discharge energy E_{DCHG} is zero.

The stationary storage control system 52 also establishes the charging instructions which it sends to the charger 53, depending on its energy needs. This step is terminated if f_{EOC2nd}=1 or f_{EOC}=1.

As regards the discharging of the battery 50 to be checked, the procedure is similar to that used for the charging. Specifically, the stationary storage control system 52 will exploit the second phase of supply in which the need of the user of is that of supplying energy, in order to engage as a priority the battery 50 subjected to the residual capacity check.

To ensure repeatability and representativity of the measurement, an additional constraint is added on the discharge power of said battery 50. The stationary storage control system 52 fixes a predetermined discharge power value in order to discharge the selected battery 50 during the discharging phase, said selected battery 50 discharging only at this predetermined discharge power value. Preferably, the predetermined discharge power value is a maximum discharge power value, the selected battery 50 ceasing to discharge if said network requires a supply power value less than said maximum discharge power value. The supply power corresponds to the power demanded by the network to supply electrical equipment connected to it. Under these conditions, only the needs of the user greater than this power will allow said battery 50 to continue discharging.

During this step, the stationary storage control system, 52 prohibits charging and establishes that:
P_{DCHG,MIN}=min(P_{DCHG,HVB}, P_{INV}) where P_{DCHG,MIN} is the minimum achievable power for the discharging depending on the precision of the measurement instruments of the storage system; P_{DCHG,HVB} is the discharge power that the battery 50 can support without being damaged; P_{INV} is the achievable power of the inverter 54;
the charge power is zero;
P_{DCHG,MAX}=min(P_{DCHG,HVB}, P_{INV}) where P_{DCHG,MAX} is the maximum achievable power for the discharging depending on the precision of the measurement instruments of the storage system;
the charge energy E_{CHG} is zero;
the discharge energy E_{DCHG} is equal to the available charge energy of the battery E_{2nd}.

The stationary storage control system 52 also establishes the discharging instructions which it sends to the inverter 54, depending on its energy needs. To ensure repeatability of the discharging tests, the stationary storage control system 52 (preferably the stationary storage control system 56) increases the minimum discharge power such that P_{DCHG,MIN}=P_{DCHG,MAX}.

The stationary storage control system 52 performs the count of yielded energy E_{ResChk} of the battery 50, each time the energy needs allow it to authorize discharging. The yielded energy level is calculated as follows:

E_{ResChk}=0.001·∫V_{HVB}·I_{HVB}·dt

V_{HVB} is the voltage at which the battery discharges I_{HVB} is the intensity at which the battery discharges. This step is terminated if f_{EODC}=1. These are the voltage and current values measured at the battery terminals.

Thus, after the selected battery is completely discharged, the stationary storage system calculates the level of energy yielded E_{resChk} by the selected battery 50. The yielded energy level E_{resChk} is compared with said guaranteed minimum energy level E_{2nd,MIN} of the battery 50.

If the yielded energy level E_{resChk} is greater than or equal to the guaranteed minimum energy level E_{2nd,MIN} of the battery 50, the stationary storage system 56 equipped with the stationary storage control system 52, which comprises an insufficient capacity check counter, resets this counter.

If the yielded energy level E_{resChk} is less than the guaranteed minimum energy level of the battery 50:
the counter is incremented by one unit at each comparison of the yielded energy level E_{resChk} and the guaranteed minimum energy level E_{2nd,MIN};
if the counter exceeds a predetermined threshold value, then information to replace this battery 50 is sent by the storage system 52, or, an end-of-charge voltage of the battery 50 is incremented.

1-9. (canceled)

10. A method for estimating residual capacities of a plurality of batteries connected to an electrical power distribution network, said method comprising:
storing, via a storage phase, in the plurality of batteries energy coming from the network;
releasing, via a release phase, to return the energy to the network;
gathering information relating to physical quantities in order to determine astute of ageing of each of the batteries from said plurality of batteries;
selecting a battery from said plurality of batteries based on information gathered and/or information relating to a planning of the use of the batteries and/or a user instruction;
during the energy storage phase, charging as a priority said selected battery until a predefined maximum charge level, dependent on the state of ageing, is reached;
during the energy release phase, discharging as a priority said selected battery, if said selected battery has reached the maximum charge level during the storage phase, until a predefined minimum charge level, dependent on the state of ageing, is reached, or making said selected battery inactive if said selected battery has not yet reached the predefined maximum charge level, then measuring a level of energy yielded by said selected battery; and
calculating a residual capacity of said selected battery based on the measurement of the level of energy yielded by said battery.

11. The estimating method as claimed in claim 10, wherein the phase for measuring the yielded energy level includes making said battery inactive if said battery still exhibits a state of charge greater than said predefined minimum charge level, while the system is passed back into a storage phase.

12. The estimating method as claimed in claim 10, further comprising fixing a predetermined discharge power value in order to discharge, during the release phase, the selected battery, said selected battery discharging only at this predetermined discharge power value, the selected battery ceasing to discharge if the network requires a supply power value less than said discharge power value.

13. The estimating method as claimed in claim 10, further comprising:
also processing the gathered information relating to physical quantities in order to detect the presence of an anomaly of the physical quantities in the battery; and
selecting as a priority, in order to be charged, the battery exhibiting an anomaly of the physical quantities, the information relating to the planning of the use of the batteries and/or the user instruction then taking lower priority.

14. The estimating method as claimed in claim 10, wherein the steps are triggered regularly.

15. The estimating method as claimed in claim 10, wherein the steps are triggered periodically.

16. The estimating method as claimed in claim 10, wherein the method is implemented by a stationary storage system.

17. The estimating method as claimed in claim 14, further comprising comparing said yielded energy level with a guaranteed minimum energy level of the se battery and:
when the yielded energy level is greater than or equal to the guaranteed minimum energy level, resetting an insufficient capacity cheek counter, or
when the yielded energy level is less than the guaranteed minimum energy level:
incrementing the counter by one unit, and
when the counter exceeds a predetermined threshold value, then information to replace the battery is sent, or, an end-of-charge voltage of the battery is incremented.

18. A system for estimating residual capacities of a plurality of batteries, comprising:
means for implementing the method as claimed in claim 10.

19. A building, comprising:
the system as claimed in claim 18.
